(19) United States
(12) Patent Application Publication
(10) Pub. No.: US 2022/0263042 A1
(43) Pub. Date: Aug. 18, 2022

(54) NEAR INFRA-RED LIGHT EMITTING DIODES

(71) Applicant: National University of Singapore, Singapore (SG)

(72) Inventors: Zhi Kuang Tan, Singapore (SG); ChenChao Xie, Singapore (SG); Xiaofei Zhao, Singapore (SG)

(21) Appl. No.: 17/626,428

(22) PCT Filed: Jul. 14, 2020
(86) PCT No.: PCT/SG2020/050405

§ 371 Date: Jan. 11, 2022

Related U.S. Application Data
(60) Provisional application No. 62/874,154, filed on Jul. 15, 2019.

(30) Foreign Application Priority Data
May 11, 2020 (SG) 10202004326P

(51) Int. Cl. H01L 51/50; H01L 51/52

(52) U.S. Cl. CPC H01L 51/5056; H01L 51/5012; H01L 51/502; H01L 51/5215; H01L 51/0077; H01L 51/5064; H01L 51/508; H01L 2251/558; H01L 2251/552; H01L 51/5234

(57) ABSTRACT

Disclosed herein is a near infra-red light emitting diode (LED) device comprising a first electrode, a second electrode and a near infra-red emitter module sandwiched between the first and second electrodes, wherein the first and second electrodes are transparent. Also disclosed herein is a near infra-red light emitting diode (LED) device comprising, a first electrode and a second electrode, a hole transport layer, an emission layer, and an electron transport layer, wherein the hole transport layer is formed from a polymeric material that has an ionisation potential of from 0 to −5.30 eV.

### FIELD OF INVENTION

The current invention relates to a near infra-red light emitting diode (LED) device comprising transparent electrodes and a near infra-red emitter module, and the application of said device in wearable and/or medical devices.

### BACKGROUND

The listing or discussion of a prior-published document in this specification should not necessarily be taken as an acknowledgement that the document is part of the state of the art or is common general knowledge.

Mobile and wearable devices have emerged as a trend in continuous health monitoring, gaming and virtual or augmented reality. These gadgets are increasingly reliant on near-infrared (NIR) covert illumination for facial recognition, eye-tracking, health-tracking or motion and depth sensing functions. However, these small devices offer limited spatial real-estate, which is typically occupied by their full-area electronic colour displays. As such, the integration of a conventional NIR light-emitting diode (LED) chip into these devices can be difficult to achieve due to the limited space available.

Perovskite and quantum dot based light-emitting diodes have recently shown promise in high-performance NIR emission, which may be suitable for mobile and wearable devices. In particular, perovskite LED has advanced rapidly, with the efficiencies of electroluminescent devices progressing quickly from 0.8% in earlier works to over 20% in more recent reports. The primary advantage that perovskite LEDs offer over other semiconductor chip-based LEDs lies in their ability to be constructed over large-areas on a variety of substrates, thus allowing them to be suited for electroluminescent display applications such as in televisions, smart-phones and smart-watches.

While high efficiencies have been successfully demonstrated, most of the reported perovskite LED devices show broad variation in performance across multiple device pixels. Such variations pose significant challenges towards commercial use, as they limit the scaling size of the devices and reduce the yield of production. The variations in device performance have conventionally been attributed to non-uniformity in the solution-processed perovskite layer, where stochastic occurrence of pinholes or defective sites is speculated to lead to poorer performance. In addition, these opaque LEDs would still occupy valuable space on the mobile or wearable device.

Given the above, there remains a need to develop new NIR-emitting LED devices to address one or more of the above problems. Importantly, these devices need to have high efficiency and can be scaled up reproducibly. The devices should also be easy to integrate into mobile or wearable gadgets. In addition, such devices need to possess stable performance and long device lifespan for use in mobile, wearable and/or medical devices. In other words, there remains a need to find ways to integrate NIR LED and electroluminescent LED technologies into space-constrained devices in a way that does not significantly impair the desired functionality of either component. If such an arrangement is possible, an array of new security and sensing functions on tech-gadgets would be possible, and may even free up space for extra functionalities. Examples of new features could include facial recognition, eye-tracking, motion and depth sensing or invisible QR security codes on smart-watches, phones, gaming consoles and augmented reality (AR) or virtual reality (VR) devices.

### SUMMARY OF INVENTION

Aspects and embodiments of the invention will now be described by reference to the following numbered clauses.

1. A near infra-red light emitting diode (LED) device comprising a first electrode, a second electrode and a near infra-red emitter module sandwiched between the first and second electrodes, wherein the first and second electrodes are transparent.

2. The LED device according to Clause 1, wherein the near infra-red emitter module comprises:
a hole transport layer;
an emission layer; and
an electron transport layer, where

the hole transport layer and electron transport layer sandwich the emission layer.

3. The LED device according to Clause 2, wherein the emission layer is formed from a material that has an optical energy gap of from 1.8 eV to 0.3 eV.

4. The LED device according to Clause 3, wherein the emission layer is formed from a semiconductor material.

5. The LED device according to Clause 4, wherein the semiconductor material is a perovskite or quantum dots, optionally wherein the quantum dots comprise one or more of the group selected from InAs, InP, PbS, PbSe and CdTe.

6. The LED device according to Clause 5, wherein the perovskite has the formula:

ABX₃

wherein:

X is a halogen anion selected from one or more of Br, CI, I;

A is a monovalent cation selected from one or more of Cs, an alkylammonium ion, and a formamidinium ion; and

B is a divalent cation selected from one or more of Pb and Sn, optionally wherein the perovskite is selected from one or more of formamidinium lead iodide (FAPbI₃), methylammonium lead iodide (MAPbI₃), cesium lead iodide (CsPbI₃), formamidinium lead bromide (FAPbBr₃), methylammonium tin iodide (MASnI₃), methylammonium tin bromide (MASnBr₃).

7. The LED device according to any one of Clauses 2 to 6, wherein the electron transport layer:

(a) is formed from one or more of 2,2′,2″-(1,3,5-benzinetriyl)-tris(1-phenyl-1-H-benzimidazole) (TPBi), 1,3,5-tri(m-pyridin-3-ylphenyl)benzene (TmPyPB), 3,3′,3″-[borylidynetris(2,4,6-trimethyl-3,1-phenylene)]tris[pyridine] (3TPYMB), 4,6-bis(3,5-di(pyridin-3-yl)phenyl)-2-methylpyrimidine (B3PYMPM), poly(9,9-di-n-octylfluorenyl-2,7-diyl) (F8), 2,4,6-Tris[3-(diphenylphosphinyl)phenyl]-1,3,5-triazine (PO-T2T), zinc oxide, and aluminium zinc oxide (e.g. zinc oxide and aluminium zinc oxide); and/or

(b) has a thickness of from 5 to 200 nm, such as from 10 to 100 nm.

8. The LED device according to any one of Clauses 2 to 7, wherein the hole transport layer:

(a) is formed from one or more of poly(9-vinylcarbazole) (PVK), poly[bis(4phenyl)(2,4,6-trimethylphenyl)amine] (PTAA), poly(3,4-ethylenedioxythiophene)-poly(styrenesulfonate) (PEDOT:PSS), nickel oxide (NiOx), tris(4-carbazoyl-9-ylphenyl)amine (TCTA), 4,4-bis(N-carbazolyl)-1,1′-biphenyl (CBP), poly(9,9-dioctylfluorene-alt-N-(4-sec-butylphenyl)-diphenylamine (TFB), and poly[N,N′-bis(4-butylphenyl)-N,N′-bisphenylbenzidine] (poly-TPD); and/or

(b) has a thickness of from 5 to 200 nm, such as from 10 to 100 nm.

9. The LED device according to Clause 8, wherein the hole transport layer is formed from Poly-TPD.

10. The LED device according to any one of Clauses 2 to 9, wherein the near infra-red emitter module further comprises:

(a) a low workfunction interlayer arranged next to the electron transport layer, said low workfunction interlayer is selected from one or more of the group consisting of polyethylenimine ethoxylated (PEIE), polyethylenimine (PEI), poly[(9,9-dioctyl-2,7-fluorene)-alt-(9,9-bis(3′-(N,N-dimethylamino)propyl)-2,7-fluorene)] (PFN), and LiF, optionally wherein the low function interlayer has a thickness of from 1 to 20 nm; and/or

(b) a high workfunction interlayer arranged next to the hole transport layer, said high workfunction interlayer is selected from one or more of the group consisting of MoO₃, WO₃, perfluorinated ionomer (PFI), optionally wherein the high workfunction interlayer has a thickness of from 1 to 20 nm.

11. The LED device according to Clause 10, wherein the near infra-red emitter module is one which has the following sequential layers:

an electron transport layer formed from aluminium zinc oxide;

a low workfunction interlayer formed from polyethylenimine ethoxylated (PEIE);

an emission layer formed from FAPbI₃;

a hole transport layer formed from poly-TPD; and

a high workfunction interlayer formed from MoO₃, where

the electron transport layer is in direct contact with the first electrode and the high workfunction interlayer is in direct contact with the second electrode, or vice versa.

12. The LED device according to any one of the preceding clauses, wherein the first and/or second electrode has an average transmittance of from 30 to 100% at a wavelength of from 400 to 700 nm and a sheet resistance of from 1 to 100 Ω/sq.

13. The LED device according to any one of the preceding clauses, wherein the first and/or second electrode is formed from an Al layer, a first layer of ITO, a Ag layer, and a second layer of ITO, where the first and second layers of ITO can independently be substituted for a layer of fluorine doped tin oxide (FTO), or a layer of silver nanowires.

14. The LED device according to Clause 13, wherein:

the Al layer has a thickness of from 5 to 20 nm; and/or

the first layer of ITO has a thickness of from 20 to 200 nm; and/or

the Ag layer has a thickness of from 5 to 20 nm; and/or

the second layer of ITO has a thickness of from 20 to 200 nm, where the first and second layers of ITO can independently be substituted for a layer of fluorine doped tin oxide (FTO), or a layer of silver nanowires, such as a device wherein:
the Al layer has a thickness of from 5 to 20 nm; and/or
the first layer of ITO has a thickness of from 20 to 60 nm; and/or
the Ag layer has a thickness of from 5 to 20 nm; and/or
the second layer of ITO has a thickness of from 20 to 60 nm, where the first and second layers of ITO can independently be substituted for a layer of fluorine doped tin oxide (FTO), or a layer of silver nanowires.

15. The LED device according to Clause 14, wherein:

the Al layer has a thickness of from 10 nm;

the first layer of ITO has a thickness of from 40 nm;

the Ag layer has a thickness of from 10 nm; and

the second layer of ITO has a thickness of from 40 nm, where the first and second layers of ITO can independently be substituted for a layer of fluorine doped tin oxide (FTO), or a layer of silver nanowires.

16. The LED device according to any one of the preceding clauses, wherein one of the first and second electrodes is formed from fluorine doped tin oxide (FTO), silver nanowires and indium tin oxide (ITO).

17. A near infra-red light emitting diode (LED) device comprising:
a first electrode and a second electrode;
a hole transport layer;
an emission layer; and
an electron transport layer, wherein:

the hole transport layer is formed from a polymeric material that has an ionisation potential of from 0 to −5.30 eV;

the hole transport layer and electron transport layer sandwich the emission layer; and

the first electrode is adjacent to the electron transport layer and the second electrode is adjacent to the hole transport layer, or vice versa.

18. The LED device according to Clause 17, wherein the energy difference the first or second electrode and the hole transport layer, whichever the hole transport layer is adjacent to, is more than 1.50 eV, such as from 1.5 to 2.0 eV, such as from 1.6 to 1.8 eV, such as 1.72 eV.

19. The LED device according to Clause 17 or Clause 18, wherein the emission layer is formed from a material that has an optical energy gap of from 1.8 eV to 0.3 eV.

20. The LED device according to any one of Clauses 17 to 19, wherein the emission layer is formed from a semiconductor material.

21. The LED device according to any one of Clauses 17 to 20, wherein the semiconductor material is a perovskite or quantum dots, optionally wherein the quantum dots comprise one or more of the group selected from InAs, InP, PbS, PbSe and CdTe.

22. The LED device according to Clause 21, wherein the perovskite has the formula:

ABX₃

wherein:

X is a halogen anion selected from one or more of Br, CI, I;

A is a monovalent cation selected from one or more of Cs, an alkylammonium ion, and a formamidinium ion; and

B is a divalent cation selected from one or more of Pb and Sn, optionally wherein the perovskite is selected from one or more of formamidinium lead iodide (FAPbI₃), methylammonium lead iodide (MAPbI₃), cesium lead iodide (CsPbI₃), formamidinium lead bromide (FAPbBr₃), methylammonium tin iodide (MASnI₃), methylammonium tin bromide (MASnBr₃).

23. The LED device according to any one of Clauses 17 to 22, wherein the electron transport layer:

(a) is formed from one or more of 2,2′,2″-(1,3,5-benzinetriyl)-tris(1-phenyl-1-H-benzimidazole) (TPBi), 1,3,5-tri(m-pyridin-3-ylphenyl)benzene (TmPyPB), 3,3′,3″-[borylidynetris(2,4,6-trimethyl-3,1-phenylene)]tris[pyridine] (3TPYMB), 4,6-bis(3,5-di(pyridin-3-yl)phenyl)-2-methylpyrimidine (B3PYMPM), poly(9,9-di-n-octylfluorenyl-2,7-diyl) (F8), 2,4,6-Tris[3-(diphenylphosphinyl)phenyl]-1,3,5-triazine (PO-T2T), zinc oxide, and aluminium zinc oxide (e.g. zinc oxide and aluminium zinc oxide); and/or

(b) has a thickness of from 5 to 200 nm, such as from 10 to 100 nm.

24. The LED device according to any one of Clauses 17 to 23, wherein the hole transport layer:

(a) is formed from one or more of poly(9-vinylcarbazole) (PVK), poly[bis(4-phenyl)(2,4,6-trimethylphenyl)amine] (PTAA), poly(3,4-ethylenedioxythiophene)-poly(styrenesulfonate) (PEDOT:PSS), nickel oxide (NiOx), tris(4-carbazoyl-9-ylphenyl)amine (TCTA), 4,4-bis(N-carbazolyl)-1,1′-biphenyl (CBP), poly(9,9-dioctylfluorene-alt-N-(4-sec-butylphenyl)-diphenylamine (TFB), and poly[N,N′-bis(4-butylphenyl)-N,N′-bisphenylbenzidine] (poly-TPD); and/or

(b) has a thickness of from 5 to 200 nm, such as from 10 to 100 nm.

25. The LED device according to Clause 24, wherein the hole transport layer is formed from Poly-TPD.

26. The LED device according to any one of Clauses 17 to 25, wherein the near infra-red emitter module further comprises:

(a) a low workfunction interlayer arranged next to the electron transport layer, said low workfunction interlayer is selected from one or more of the group consisting polyethylenimine ethoxylated (PEIE), polyethylenimine (PEI), poly[(9,9-dioctyl-2,7-fluorene)-alt-(9,9-bis(3′-(N,N-dimethylamino)propyl)-2,7-fluorene)] (PFN), and LiF, optionally wherein the low function interlayer has a thickness of from 1 to 20 nm; and/or

(b) a high workfunction interlayer arranged next to the hole transport layer, said high workfunction interlayer is selected from one or more of the group consisting of MoO₃, WO₃, perfluorinated ionomer (PFI), optionally wherein the high workfunction interlayer has a thickness of from 1 to 20 nm.

27. The LED device according to Clause 26, wherein the near infra-red emitter module is one which has the following sequential layers:

an electron transport layer formed from aluminium zinc oxide;

a low workfunction interlayer formed from polyethylenimine (PEIE);

an emission layer formed from FAPbI₃;

a hole transport layer formed from poly-TPD; and

a high workfunction interlayer formed from MoO₃, where

the electron transport layer is in direct contact with the first electrode and the high workfunction interlayer is in direct contact with the second electrode, or vice versa.

28. The LED device according to any one of Clauses 17 to 27, wherein the first and/or second electrode has an average transmittance of from 30 to 100% at a wavelength of from 400 to 700 nm and a sheet resistance of from 1 to 100 Ω/sq.

29. The LED device according to any one of Clauses 17 to 28, wherein the first and/or second electrode is formed from:

(a) a layer of aluminium; or

(b) an AI layer, a first layer of ITO, a Ag layer, and a second layer of ITO, where the first and second layers of ITO can independently be substituted for a layer of fluorine doped tin oxide (FTO), or a layer of silver nanowires.

30. The LED device according to Clause 29, wherein:

the Al layer has a thickness of from 5 to 20 nm; and/or

the first layer of ITO has a thickness of from 20 to 200 nm; and/or

the Ag layer has a thickness of from 5 to 20 nm; and/or

the second layer of ITO has a thickness of from 20 to 200 nm, where the first and second layers of ITO can independently be substituted for a layer of fluorine doped tin oxide (FTO), or a layer of silver nanowires, such as a device wherein:
the Al layer has a thickness of from 5 to 20 nm; and/or
the first layer of ITO has a thickness of from 20 to 60 nm; and/or
the Ag layer has a thickness of from 5 to 20 nm; and/or
the second layer of ITO has a thickness of from 20 to 60 nm, where the first and second layers of ITO can independently be substituted for a layer of fluorine doped tin oxide (FTO), or a layer of silver nanowires.

31. The LED device according to Clause 30, wherein:

the Al layer has a thickness of from 10 nm;

the first layer of ITO has a thickness of from 40 nm;

the Ag layer has a thickness of from 10 nm; and

the second layer of ITO has a thickness of from 40 nm, where the first and second layers of ITO can independently be substituted for a layer of fluorine doped tin oxide (FTO), or a layer of silver nanowires.

32. The LED device according to any one of Clauses 17 to 31, wherein one of the first and second electrodes is formed from fluorine doped tin oxide (FTO), silver nanowires and indium tin oxide (ITO).

33. The LED device according to any one of Clauses 17 to 31, wherein:

(a) the LED device emits at about 799 nm and have a full width at half maximum of 41 nm; and/or

(b) a 2×2 mm² LED device has a radiance of from 150 to 200 (e.g. 170) W sr⁻¹ m⁻² at a driving voltage of 4.0 V and a current density of 187 mA cm⁻²; and/or

(c) a 2×2 mm² LED device has an efficiency of from 16 to 22% (e.g. from 17 to 20.5%) when measured at a radiance of 57 W sr⁻¹ m⁻² and a current density of 57 mA cm⁻²; and/or

(d) a 2×2 mm² LED device has an average efficiency of from 16 to 18% (e.g. 17.4%) when measured at a radiance of 57 W sr⁻¹ m⁻² and a current density of 57 mA cm⁻²; and/or

(e) a 2×2 mm² LED device has a T₈₀ lifetime of from 15 to 30 hours, such as 20 hours; and/or

(f) the device has a hole current and an electron current, where the hole current is from 0.5 to 2 times that of the electron current.

### DRAWINGS

FIG. 1 Depicts: (a) the general layout of PeLED device 100 of the current invention, which comprises a near infra-red light emitting diode (NIR LED) module 105 sandwiched between a top and bottom electrodes (110 and 150). The module 105 comprises a hole transport layer 140, an emission layer 130, and an electron transport layer 120, where the hole transport layer 140 and electron transport layer 120 sandwich the emission layer 130; (b) PeLED device 200 (ITO/ZnO/PEIE/FAPbI₃/Poly-TPD/MoO₃/Al) of the current invention; and (c) PeLED 300 (ITO/AZO/PEIE/FAPbI₃/poly-TPD/MoO₃/Al/ITO/Ag/ITO) of the current invention. The arrows depict NIR emission from the device.

FIG. 2 Depicts the absorbance and photoluminescence spectra of FAPbI₃ perovskite.

FIG. 3 Depicts: (a) a scanning electron microscopy (SEM) image; and (b) an atomic force microscopy (AFM) image of FAPbI₃ perovskite layer on a device substrate.

FIG. 4 Depicts the characterisation and performance of ITO/ZnO/PEIE/FAPbI₃/Poly-TPD/MoO₃/Al PeLED device 200: (a) device structure, electroluminescence spectra and near infra-red photo of PeLED 200; (b) combined current density vs. voltage, and radiance vs. voltage plots of the PeLED 200; (c) external quantum efficiency vs. current density of PeLED; (d) histogram of the efficiencies of 40 device 200; and (e) lifetime plot of PeLED 200 at constant current density of 57 mA cm⁻².

FIG. 5 Depicts the performance of control devices (ITO/ZnO/PEIE/FAPbI₃/TFB/MoO₃/Al) that incorporated fluorene-based TFB as the material for the hole transport layer: (a) the combined current density vs. voltage, and radiance vs. voltage plots of the control devices; (b) external quantum efficiency vs. current density of the control device; and (c) histogram of the efficiencies of 40 control devices.

FIG. 6 Depicts the current density vs. voltage characteristics of single-carrier devices: ITO/PEDOT:PSS/FAPbI₃/Poly-TPD/MoO₃/Al hole-only device, ITO/PEDOT:PSS/FAPbI₃/TFB/MoO₃/Al hole-only device, and ITO/ZnO/PEIE/FAPbI₃/LiF/Al electron-only device.

FIG. 7 Depicts: (a) ultraviolet photoelectron spectra of poly-TPD, TFB and FAPbI₃, showing secondary photoelectron cutoff and the ionisation edge. Binding energy is referenced with respect to the Fermi level of the system; and (b) energy level diagrams of ITO/ZnO/PEIE/FAPbI₃/Poly-TPD/MoO₃/Al (device 200, top) and ITO/ZnO/PEIE/FAPbI₃/TFB/MoO₃/Al PeLED device (bottom).

FIG. 8 Depicts the characterisation and performance of large-area ITO/ZnO/PEIE/FAPbI₃/Poly-TPD/MoO₃/Al PeLED device 200: (a) combined current density vs. voltage, and radiance vs. voltage plots of the 900 mm² PeLED 200; (b) external quantum efficiency (EQE) vs. current density of the 900 mm² PeLED 200; and (c) histogram of the efficiencies of 12 large-area devices 200.

FIG. 9 Depicts the lifetime plot of 900 mm² ITO/ZnO/PEIE/FAPbI₃/Poly-TPD/MoO₃/Al PeLED 200 at constant current density of 10 mA cm⁻².

FIG. 10 Depicts: (a and b) an near infra-red (NIR) photo of large-area PeLED 200 on glass and flexible PET substrate, respectively; (c) PeLED 200 with a 0.5-inch circular window, illuminating subcutaneous blood vessels on human palm in close contact; (d) PeLED 200 illuminating the back of a human fist; and (e) fluctuation in back-scattered NIR light intensity tracked using the PeLED 200 coupled with a silicon photodiode, which functions as an optical heart rate monitor.

FIG. 11 Depicts: (a) combined current density vs. voltage, and radiance vs. voltage plots of 900 mm² ITO/ZnO/PEIE/FAPbI₃/TFB/MoO₃/Al PeLED; and (b) EQE vs. current density of the 900 mm² PeLED.

FIG. 12 Depicts: (a) combined current density vs. voltage, and radiance vs. voltage plots of 900 mm² ITO/ZnO/PEIE/FAPbI₃/Poly-TPD/MoO₃/Al PeLED 200 on a flexible PET substrate; and (b) EQE vs. current density of 900 mm² PeLED 200 on flexible PET substrate.

FIG. 13 Depicts the characterisation and performance of transparent PeLED device 300 (ITO/AZO/PEIE/FAPbI₃/Poly-TPD/MoO₃/Al/ITO/Ag/ITO) of the current invention: (a) electroluminescence spectra of PeLED 300 from 1.6 V to 4.0 V. Inset shows an infra-red photo of a 120 mm² PeLED; (b) combined current density vs. voltage, and radiance vs. voltage plots of PeLED 300; (c) EQE vs. current density plots of PeLED 300. Solid lines represent device measurements from the front and dashed lines represent measurements from the back; and (d) transmittance spectrum of ITO glass substrate.

FIG. 14 Depicts: (a) comparison of current density and radiance between PeLED 300 (ITO/AZO/PEIE/FAPbI₃/Poly-TPD/MoO₃/Al/ITO/Ag/ITO) and an ITO/AZO/PEIE/FAPbI₃/Poly-TPD/MoO₃/ITO PeLED. Inset table shows the sheet resistance of their respective transparent electrodes; (b) comparison of optical transmittance of the PeLED devices and their respective transparent electrodes on glass. Bottom plots show the emission spectra of a typical smart watch display, and the electroluminescence (EL) spectrum of the PeLED.

FIG. 15 Depicts application of covert illumination function of the transparent PeLED 300 of the current invention on a smart watch: (a) a photo of transparent PeLED 300 overlaid across a smart watch display to show high optical transparency and neutral colour; and (b) infra-red photo showing bright NIR electroluminescence from the transparent PeLED 300 above the smart watch display.

### DESCRIPTION

Advantageously, the near infra-red light emitting diode devices disclosed are transparent (at least through one electrode), highly efficient, and can be fabricated with a large surface area. Importantly, these devices can be reproduced with high consistency (low variation). As such, these make them highly suitable for use in wearable, mobile and/or medical devices.

Thus, in a first aspect of the invention, there is provided a near infra-red light emitting diode (LED) device comprising a first electrode, a second electrode and a near infra-red emitter module sandwiched between the first and second electrodes, wherein the first and second electrodes are transparent.

In embodiments herein, the word “comprising” may be interpreted as requiring the features mentioned, but not limiting the presence of other features. Alternatively, the word “comprising” may also relate to the situation where only the components/features listed are intended to be present (e.g. the word “comprising” may be replaced by the phrases “consists of” or “consists essentially of”). It is explicitly contemplated that both the broader and narrower interpretations can be applied to all aspects and embodiments of the present invention. In other words, the word “comprising” and synonyms thereof may be replaced by the phrase “consisting of” or the phrase “consists essentially of” or synonyms thereof and vice versa.

Unless otherwise specified “transparent” when used with respect to a material herein, refers to a material that has an average transmittance of from 20% to 100% at a wavelength from 400 nm to 700 nm. In embodiments that may be mentioned herein, a transparent material may have an average transmittance of from 30 to 100% at a wavelength of from 400 to 700 nm.

For example, the current device has two transparent electrodes. As such, both electrodes may provide an average transmittance of from 20% to 100% at a wavelength from 400 nm to 700 nm. In particular examples that may be mentioned herein, the first and/or second electrode may have an average transmittance of from 30 to 100% at a wavelength of from 400 to 700 nm. In certain embodiments, the first and second electrodes may also have a sheet resistance of from 1 to 100 Ω/sq.

When used herein, “near infra-red” (NIR) refers to the region of the electromagnetic spectrum from 700 nm to 3,300 nm. For the avoidance of doubt, it is required that the peak of the emission spectrum produced by a NIR falls within the range of 700 nm to 3,300 nm.

When used herein the term “emitter module” is intended to refer to any LED device that is capable of generating NIR light. Such materials may, for example, simply require the presence of a material that can emit light at a wavelength in the NIR spectrum. In particular examples that may be mentioned herein, the near infra-red emitter module may comprise:
a hole transport layer;
an emission layer; and
an electron transport layer, where

the hole transport layer and electron transport layer sandwich the emission layer.

The emission layer refers to a material that emits light at the desired wavelength. For example, the emission layer may be formed from a material that has an optical energy gap of from 1.8 eV to 0.3 eV.

The emission layer may typically be formed from a semiconductor material, which material may exhibit an optical energy gap of from 1.8 eV to 0.3 eV. Examples of suitable semiconductor materials include, but are not limited to, perovskite or quantum dots. As will be appreciated, any quantum dot or perovskite material that is capable of emitting NIR radiation may be used in the current invention.

Examples of quantum dots that may be used herein include, but are not limited to quantum dots formed from InAs, InP, PbS, PbSe and CdTe (or combinations of these quantum dots).

A perovskite material that may be used as the emission layer in embodiments herein may be one that has the formula:

ABX₃

wherein:

X is a halogen anion selected from one or more of Br, CI, I;

A is a monovalent cation selected from one or more of Cs, an alkylammonium ion, and a formamidinium ion; and

B is a divalent cation selected from one or more of Pb and Sn.

Particular examples of perovskites that may be used as the emission layer include, but are not limited to, formamidinium lead iodide (FAPbI₃), methylammonium lead iodide (MAPbI₃), cesium lead iodide (CsPbI₃), formamidinium lead bromide (FAPbBr₃), methylammonium tin iodide (MASnI₃), methylammonium tin bromide (MASnBr₃), and combinations thereof. For example, the perovskite may be FAPbI₃.

When used in embodiments disclosed herein, the emission layer may also comprise (in addition to the emission material) an enhancement additive. Examples of enhancement additives include, but are not limited to polyethylene oxide (PEO), 18-crown-6, cyclam, 2,2′-[oxybis(ethylenoxy)]diethylamine (ODEA), and 5-aminovaleric acid (5AVA). In embodiments described herein, the perovskite emission layer may be formed from FAPbI₃ along with 5AVA. The weight to weight ratio of emission material to enhancement additive (when the latter is present) may be from 5:1 to 10:1, such as from 6:1 to 8:1, such as about 7.87:1.

When used herein, “electron transport layer” refers to a material that may act to inject electrons into the emission layer. Examples of suitable materials for the electron transport layer include, but are not limited to 2,2′,2″-(1,3,5-benzinetriyl)-tris(1-phenyl-1-H-benzimidazole) (TPBi), 1,3,5-tri(m-pyridin-3-ylphenyl)benzene (TmPyPB), 3,3′,3″-[borylidynetris(2,4,6-trimethyl-3,1-phenylene)]tris[pyridine] (3TPYMB), 4,6-bis(3,5-di(pyridin-3-yl)phenyl)-2-methylpyrimidine (B3PYMPM), poly(9,9-di-n-octylfluorenyl-2,7-diyl) (F8), 2,4,6-Tris[3-(diphenylphosphinyl)phenyl]-1,3,5-triazine (PO-T2T), zinc oxide, aluminium zinc oxide and combinations thereof. In particular embodiments that may be mentioned herein, the electron transport layer may be selected from zinc oxide and/or aluminium zinc oxide.

When present in the emitter module, the electron transport layer may have any suitable thickness, which can be readily determined by a person skilled in the art. Examples of suitable thicknesses include, but are not limited to a thickness of from 5 to 200 nm, such as from 10 to 100 nm.

When used herein “hole transport layer” refers to a material that may act to inject holes (i.e. positive charge carriers) into the emission layer. Examples of suitable materials for the hole transport layer include, but are not limited to poly(9-vinylcarbazole) (PVK), poly[bis(4-phenyl)(2,4,6-trimethylphenyl)amine] (PTAA), poly(3,4-ethylenedioxythiophene)-poly(styrenesulfonate) (PEDOT:PSS), nickel oxide (NiOx), tris(4-carbazoyl-9-ylphenyl)amine (TCTA), 4,4-bis(N-carbazolyl)-1,1′-biphenyl (CBP), poly(9,9-dioctylfluorene-alt-N-(4-sec-butylphenyl)-diphenylamine (TFB), and poly[N,N′-bis(4-butylphenyl)-N,N′-bisphenylbenzidine] (poly-TPD). In particular embodiments that may be mentioned herein, the hole transport layer may be poly-TPD.

When present in the emitter module, the hole transport layer may have any suitable thickness, which can be readily determined by a person skilled in the art. Examples of suitable thicknesses include, but are not limited to a thickness of from 5 to 200 nm, such as from 10 to 100 nm.

In embodiments where the hole transport layer, emission layer and electron transport layer are used to form the emitter module, additional component layers may also be present. For example, the near infra-red emitter module may further comprise a low workfunction interlayer arranged next to the electron transport layer and/or a high workfunction interlayer arranged next to the hole transport layer.

Suitable materials that may be used to form the low workfunction interlayer includes, but is not limited to, polyethylenimine ethoxylated (PEIE), polyethylenimine (PEI), poly[(9,9-dioctyl-2,7-fluorene)-alt-(9,9-bis(3′-(N,N-dimethylamino)propyl)-2,7-fluorene)) (PFN), LiF and combinations thereof. When present in the emitter module, the low workfunction interlayer may have any suitable thickness, which can be readily determined by a person skilled in the art Examples of suitable thicknesses include, but are not limited to a thickness of from 1 to 20 nm.

Suitable materials that may be used to form the high workfunction interlayer includes, but is not limited to, MoO₃, WO₃, perfluorinated ionomer (PFI) and combinations thereof. When present in the emitter module, the high workfunction interlayer may have any suitable thickness, which can be readily determined by a person skilled in the art. Examples of suitable thicknesses include, but are not limited to a thickness of from 1 to 20 nm.

In particular embodiments of the invention that may be mentioned herein, the near infra-red emitter module may be one which has the following sequential layers:

an electron transport layer formed from aluminium zinc oxide;

a low workfunction interlayer formed from polyethylenimine ethoxylated (PEIE);

an emission layer formed from FAPbI₃;

a hole transport layer formed from poly-TPD; and

a high workfunction interlayer formed from MoO₃, where

the electron transport layer is in direct contact with the first electrode and the high workfunction interlayer is in direct contact with the second electrode, or vice versa.

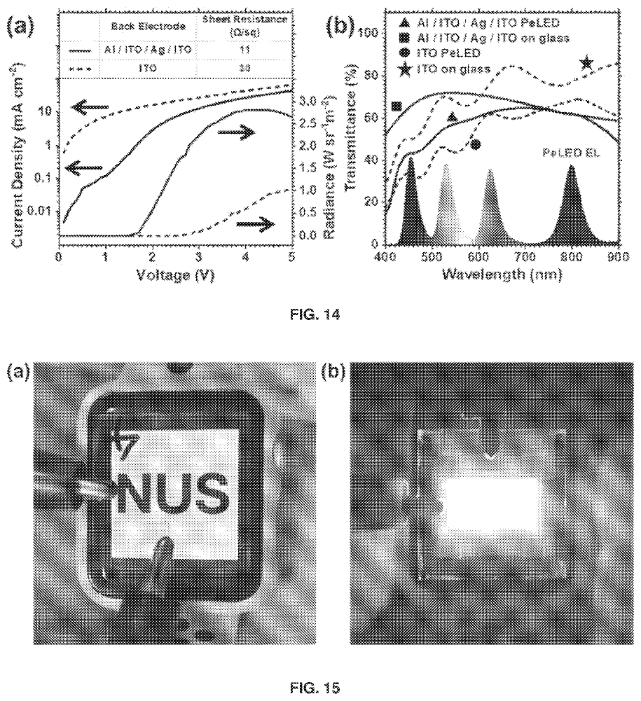

As noted above, the electrodes of this aspect of the invention are transparent. While any transparent electrode may be used, it is believed that at least one electrode formed from an Al layer, a first layer of ITO, a Ag layer, and a second layer of ITO may be particularly useful. For completeness, it is noted that each of the ITO layers mentioned above may each be independently replaced by fluorine doped tin oxide (FTO) or silver nanowires. As will be appreciated, in particular embodiments of the invention, the first and second layers of ITO are not substituted by other materials. Without wishing to be bound by theory, it is believed that the composition of this electrode allows one to obtain better performance from the resulting LED, as compared to the use of a monolayer of ITO or a substitute material thereof. This is because it has been noted that sputtering ITO onto the formed surface of the emitter module can create defects that reduce the final product's performance. In contrast, by using the layers of the electrode above—at least for the electrode formed onto the surface of the emitter module—results in fewer of no defects in the surface of the emitter module and hence improved performance. Further, the use of the layers of electrodes may provide lower sheet resistance, which is required for the LED to operate efficiently. This is discussed in more detail in the experimental section below (i.e. Example 6 and FIGS. 14a and b).

In an example of an LED device according to this aspect, the first or second electrode may be one on which one or more of the following apply:

the Al layer has a thickness of from 5 to 20 nm;

the first layer of ITO has a thickness of from 20 to 200 nm;

the Ag layer has a thickness of from 5 to 20 nm; and

the second layer of ITO has a thickness of from 20 to 200 nm, where the first and second layers of ITO can independently be substituted for a layer of fluorine doped tin oxide (FTO), or a layer of silver nanowires.

For the avoidance of doubt, the first or the second electrode may be one having the following combinations:

(a) one where the Al layer has a thickness of from 5 to 20 nm;

(b) one where the first layer of ITO has a thickness of from 20 to 200 nm;

(c) one where the Ag layer has a thickness of from 5 to 20 nm;

(d) one where the second layer of ITO has a thickness of from 20 to 200 nm;

(e) one where the Al layer has a thickness of from 5 to 20 nm and the first layer of ITO has a thickness of from 20 to 200 nm;

(f) one where the Al layer has a thickness of from 5 to 20 nm and the Ag layer has a thickness of from 5 to 20 nm;

(g) one where the Al layer has a thickness of from 5 to 20 nm and the second layer of ITO has a thickness of from 20 to 200 nm;

(h) one where the first layer of ITO has a thickness of from 20 to 200 nm and the Ag layer has a thickness of from 5 to 20 nm;

(i) one where the first layer of ITO has a thickness of from 20 to 200 nm and the second layer of ITO has a thickness of from 20 to 200 nm;

(j) one where the Ag layer has a thickness of from 5 to 20 nm and the second layer of ITO has a thickness of from 20 to 200 nm;

(k) one where the Al layer has a thickness of from 5 to 20 nm, the first layer of ITO has a thickness of from 20 to 200 nm, and the Ag layer has a thickness of from 5 to 20 nm;

(l) one where the Al layer has a thickness of from 5 to 20 nm, the first layer of ITO has a thickness of from 20 to 200 nm, and the second layer of ITO has a thickness of from 20 to 200 nm;

(m) one where the Al layer has a thickness of from 5 to 20 nm, the Ag layer has a thickness of from 5 to 20 nm, and the second layer of ITO has a thickness of from 20 to 200 nm; and

(n) one where the Al layer has a thickness of from 5 to 20 nm, the first layer of ITO has a thickness of from 20 to 200 nm, the Ag layer has a thickness of from 5 to 20 nm, and the second layer of ITO has a thickness of from 20 to 200 nm.

In further embodiments, the first or second electrode may be one in which:
the Al layer has a thickness of from 5 to 20 nm; and/or
the first layer of ITO has a thickness of from 20 to 60 nm; and/or
the Ag layer has a thickness of from 5 to 20 nm; and/or
the second layer of ITO has a thickness of from 20 to 60 nm, where the first and second layers of ITO can independently be substituted for a layer of fluorine doped tin oxide (FTO), or a layer of silver nanowires.

For example, in particular embodiments of the first aspect of the invention that may be mentioned herein, the first or second electrode may be one in which:

the Al layer has a thickness of from 10 nm;

the first layer of ITO has a thickness of from 40 nm;

the Ag layer has a thickness of from 10 nm; and

the second layer of ITO has a thickness of from 40 nm, where the first and second layers of ITO can independently be substituted for a layer of fluorine doped tin oxide (FTO), or a layer of silver nanowires. As will be appreciated, in particular embodiments of the invention, the first and second layers of ITO are not substituted by other materials.

While both the first and second electrode may be made of the materials discussed hereinbefore, it is also contemplated that one (or both) of the electrodes may be formed from one or more of fluorine doped tin oxide (FTO), silver nanowires and indium tin oxide (ITO). In particular embodiments that may be mentioned herein, one of the electrodes may be formed from one or more of FTO, silver nanowires and ITO (e.g. ITO), while the other may be a layered electrode as described in detail hereinbefore.

In a second aspect of the invention, there is provided a near infra-red light emitting diode (LED) device comprising:
a first electrode and a second electrode;
a hole transport layer;
an emission layer; and
an electron transport layer, wherein:

the hole transport layer is formed from a polymeric material that has an ionisation potential of from 0 to −5.30 eV;

the hole transport layer and electron transport layer sandwich the emission layer; and

the first electrode is adjacent to the electron transport layer and the second electrode is adjacent to the hole transport layer, or vice versa.

It is believed that the use of a material having an ionisation hole potential of from 0.5 to −5.30 eV results in a LED with improved properties, such as efficiency, radiance, and lifetime. Surprisingly, the devices formed using such a material may have a hole current and electron current of a similar quantum, that is, the hole current may be from 0.5 to 2 times that of the electron current.

Additionally, the properties observed may be the result of an energy difference between the first or second electrode and the hole transport layer, whichever the hole transport layer is adjacent to, is more than 1.50 eV, such as from 1.5 to 2.0 eV, such as from 1.6 to 1.8 eV, such as 1.72 eV.

The emission layer, hole transport layer, and electron layer used in this second aspect of the invention are the same as described above in respect of the first aspect of the invention and will not be described again for the sake of brevity. As in the first aspect of the invention, the LED device may also comprise low and high workfunction interlayers, which again have been described in detail above.

In this aspect of the invention, the LED device may be one which has the following sequential layers:

an electron transport layer formed from aluminium zinc oxide;

a low workfunction interlayer formed from polyethylenimine (PEIE);

an emission layer formed from FAPbI₃;

a hole transport layer formed from poly-TPD; and

a high workfunction interlayer formed from MoO₃, where

the electron transport layer is in direct contact with the first electrode and the high workfunction interlayer is in direct contact with the second electrode, or vice versa.

In this aspect of the invention, while both the first and second electrodes can be transparent, one of the electrodes may be non-transparent (e.g. the electrode that is formed onto the LED device). Nevertheless, the first and/or second electrode may have an average transmittance of from 30 to 100% at a wavelength of from 400 to 700 nm and a sheet resistance of from 1 to 100 Ω/sq.

Thus, at least one of the first and second electrodes may be formed from one of fluorine doped tin oxide (FTO), silver nanowires and indium tin oxide (ITO). For example, one of the first and second electrodes mat be formed from ITO. In embodiments where only one of the electrodes is formed from the aforementioned materials, then the other electrode may be formed from a layer of aluminium.

In embodiments of the invention where one or both of the first and second electrodes are formed from transparent materials, said electrode(s) may be formed from an Al layer, a first layer of ITO, a Ag layer, and a second layer of ITO, where the first and second layers of ITO can independently be substituted for a layer of fluorine doped tin oxide (FTO), or a layer of silver nanowires. Again, further details relating to this electrode are provided above with respect to the first aspect of the invention and will not be described again in detail here for the sake of brevity.

The device of the first and second aspect of the invention may provide improved properties relative to other NIR LED devices. A selection of these properties include, but are not limited to one or more of the following:

(a) a device where the LED device emits at about 799 nm and have a full width at half maximum of 41 nm;

(b) a 2×2 mm² LED device has a radiance of from 150 to 200 (e.g. 170) W sr⁻¹ m⁻² at a driving voltage of 4.0 V and a current density of 187 mA cm⁻²;

(c) a 2×2 mm² LED device has an efficiency of from 16 to 22% (e.g. from 17 to 20.5%) when measured at a radiance of 57 W sr⁻¹ m⁻² and a current density of 57 mA cm⁻²;

(d) a 2×2 mm² LED device has an average efficiency of from 16 to 18% (e.g. 17.4%) when measured at a radiance of 57 W sr⁻¹ m⁻² and a current density of 57 mA cm⁻²;

(e) a 2×2 mm² LED device has a T₈₀ lifetime of from 15 to 30 hours, such as 20 hours; and

(f) the device has a hole current and an electron current, where the hole current is from 0.5 to 2 times that of the electron current.

Further aspects and embodiments of the invention will be provided with respect to the following non-limiting examples.

### EXAMPLES

### Methods

Ultraviolet Photoelectron Spectroscopy (UPS)

The samples were prepared by spin-coating on Ag-coated Si substrates and were transferred into the ultrahigh vacuum chamber for measurements. The UPS measurements were performed using a Kratos Analytical, Axis Ultra DLD system, utilising the He (I) photo line (21.21 eV) from a He discharge lamp.

Photoluminescence (PL) and UV-Visible-NIR Absorption/Transmittance Spectroscopy

The photoluminescence and UV-visible absorbance spectra were measured using a calibrated Ocean Optics Flame-T and Flame-NIR spectrometer. The photoluminescence spectra were obtained by photo-exciting the film (glass/ZnO/PEIE/FAPbI₃) in an integrating sphere, using a Spectra-Physics 405 nm (100 mW, CW) diode laser. UV-visible absorbance spectra were obtained by measuring the transmitted light intensity of an Ocean Optics HL-2000 broadband light source.

The UV-Visible-NIR transmittance spectra were obtained by measuring the transmitted light intensity of an Ocean Optics HL-2000 broadband light source with a calibrated Ocean Optics Flame-T spectrometer. The transmittance of the electrodes on glass was measured using an Agilent CARY-7000 spectrophotometer.

Haze Measurement

A 990 nm diode laser beam (500 mW, CW) was transmitted through a device stack (without metal electrode), and the forward scattered intensity was collected through an integrating sphere and measured using a Flame-NIR spectrometer. The full transmitted laser intensity was measured by capturing the beam in the integrating sphere with a white scattering window. The haze of the device was determined by the ratio of scattered laser intensity to the full laser intensity.

Optical Heart Rate Monitor

A 400 mm² PeLED device with a 36 mm² clear optical window was driven at 3.5 V, and placed in close contact with a finger. A 100 mm² silicon photodiode was placed above the optical window to detect the back-scattered light, and the fluctuation in photocurrent was measured using a Thorlabs PDA200C photodiode amplifier coupled with a Tektronix MDO3024 oscilloscope.

### General Method 1—Preparation of Perovskite Precursor Solution

The formamidinium lead iodide (FAPbI₃) perovskite precursor was prepared by dissolving 27.7 mg formamidinium iodide (FAI, Xi'an Polymer Light Technology), 33.2 mg PbI₂ (Sigma-Aldrich) and 7.7 mg 5-aminovaleric acid (5-AVA, Sigma-Aldrich) in 1 mL of anhydrous N,N-dimethylformamide (DMF, Sigma-Aldrich). The precursor solution was stirred for 2 h at 80° C. in a nitrogen-filled glovebox before use.

### General Method 2—Synthesis of ZnO Nanoparticles

Zinc acetate dehydrate (Sigma-Aldrich) (2.96 g) was dissolved in 120 mL methanol at 63° C. A solution of potassium hydroxide (Sigma-Aldrich) (1.48 g) dissolved in 60 mL methanol was then added swiftly. After reacting for 2.5 h, the precipitated product was collected by decanting the solvent. The precipitate was purified three times by adding methanol and decanting. The final product was collected by centrifuge, followed by dispersion in n-butanol (Sigma-Aldrich) to a concentration of 30 mg mL⁻¹.

### General Method 3—Characterisation of as-Fabricated PeLED Devices of the Current Invention

The current density vs. voltage characteristics were measured using a Keithley 2450 source-measure unit. The voltage was swept from 0 V to 4 V at 0.2 V steps (for device 200), or at V to 5 V at 0.1 V steps (for device 300), with a delay time of 1 s. Simultaneously, the photon flux was measured using a 100 mm² Hamamatsu silicon photodiode with NIST traceable calibration at a distance of 100 mm. The electroluminescence spectra were recorded concurrently using an Ocean Optics Flame-T spectrometer. External quantum efficiency (EQE) was calculated by taking a Lambertian emission profile. The device lifetime was measured using the same setup, but under a constant current density condition. For characterisation of the transparent PeLED device 300, the front and back emission from the same transparent device were measured separately in two current-voltage sweeps using the same configuration and settings. The base below the device is dark to minimise the collection of reflected light. All device measurements and lifetime studies were performed in a dark enclosure in an argon-filled glovebox. The near infra-red (NIR) image of the light-emitting device was captured using an IR-modified Canon 200D DSLR camera in a dark enclosure.

### Example 1. Fabrication of Perovskite Light Emitting Diode (PeLED) Device 200 of the Current Invention

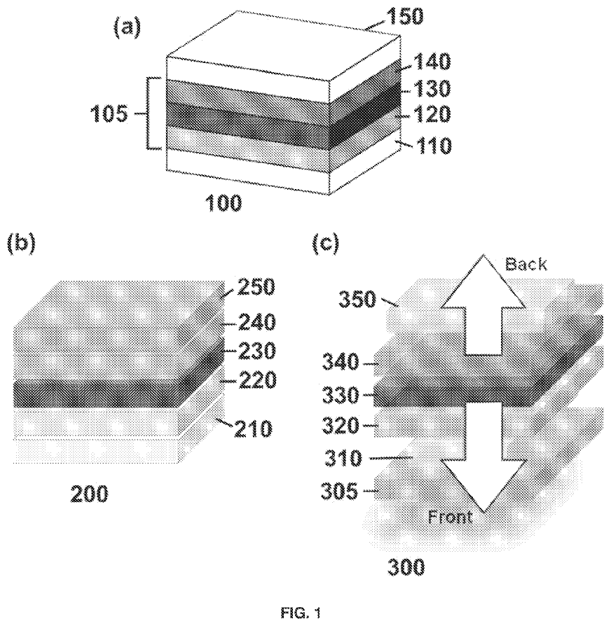

The PeLED device 100 of the current invention generally adopts the arrangement depicted in FIG. 1a, which comprises a near infra-red light emitting diode (NIR LED) module 105 sandwiched between a top and bottom electrodes (150 and 110). The module 105 comprises a hole transport layer 140, an emission layer 130, and an electron transport layer 120, where the hole transport layer 140 and electron transport layer 120 sandwich the emission layer 130.

An example of the current invention, PeLED device 200, was fabricated with its various components as shown in FIG. 1b.

### Experimental

Pre-patterned indium tin oxide (ITO)-glass substrates (8 Ω/sq) were cleaned in a detergent solution, deionised water, acetone and isopropanol for 5 min sequentially, and then dried with an argon gun. The substrates (denoted as 210 in FIG. 1b) were treated in a UV-ozone cleaner for 30 min before subsequent layers were spin coated onto them. The as-prepared ZnO nanoparticles (from general method 2) were deposited onto a substrate by spin-coating at 1500 rpm for 1 min, followed by annealing at 140° C. for 10 min to form the electron transport layer 220. After cooling down, a thin layer of polyethylenimine ethoxylated (PEIE, 2-methoxyethanol as solvent at a concentration of 0.4 wt %), which functions as a low workfunction interlayer, was spin-coated at 5000 rpm for 1 min. The layers were annealed at 110° C. for 20 min.

The substrate was then transferred into an argon-filled glove box for the deposition of subsequent layers. 40 μL of the as-prepared formamidinium lead iodide (FAPbI₃) perovskite precursor solution (from general method 1) was spin-coated to the substrate at 3000 rpm for 1 min, followed by annealing at 100° C. for 16 min to form the emission layer 230.

The poly-TPD (poly[N,N′-bis(4-butylphenyl)-N,N′-bisphenylbenzidine], American Dye Source) hole transport layer 240 was spin-coated (over the emission layer 230) from a chlorobenzene solution with a concentration of 13 mg mL⁻¹. Finally, 10 nm of MoO₃ and 50 nm of aluminium were sequentially thermal evaporated through a shadow mask at a pressure below 10⁻⁶ Torr, and deposited on the hole transport layer 240. The MoO₃ layer functions as a high workfunction interlayer, with the aluminium layer being the electrode layer 250. The area of the device (defined by the overlap between the ITO and Al electrode) was determined to be 4 mm² for the small-area devices, and 900 mm² for the large-area devices.

Device 200 may also be denoted as “ITO/ZnO/PEIE/FAPbI₃/Poly-TPD/MoO₃/Al” in the examples and figures.

In addition, a control device ITO/ZnO/PEIE/FAPbI₃/TFB/MoO₃/Al was fabricated using the fluorene-based TFB (poly(9,9-dioctylfluorene-alt-N-(4-sec-butylphenyl)-diphenylamine)) in replacement of poly-TPD.

Fabrication of Single-Carrier Devices (Hole-Only and Electron-Only)

The ITO/PEDOT:PSS/FAPbI₃/poly-TPD/MoO₃/Al hole-only device was fabricated using the same procedures for the fabrication of PeLED device 200. However, the only difference is that the ZnO/PEIE electron transport layer 220 was replaced by a poly(3,4-ethylenedioxythiophene) polystyrene sulfonate (PEDOT:PSS) layer (Clevios P VP Al 4083) by spin-coating at 5000 rpm for 1 min and annealed at 150° C. for 10 min.

The ITO/PEDOT:PSS/FAPbI₃/TFB/MoO₃/Al hole-only device was fabricated using the fluorene-based TFB in replacement of poly-TPD.

Similarly, the ITO/ZnO/PEIE/FAPbI₃/LiF/Al electron-only device was fabricated using the same procedures, except that a 1 nm layer of LiF (in replacement of 10 nm MoO₃) was deposited before Al (50 nm).

### Results and Discussion

A formamidinium lead iodide (FAPbI₃)-based PeLED in an ITO/ZnO/PEIE/FAPbI₃/Poly-TPD/MoO₃/Al device 200 was fabricated, as shown in FIG. 1b. The perovskite layer 230 was prepared using conventional formamidinium iodide and lead iodide precursors, with 5-aminovaleric acid (5-AVA) as enhancement additives. The 5-AVA additive is useful in defect passivation, and in directing the formation of microstructures for improved light extraction. The as-fabricated device was characterised, with its performance evaluated as described in Examples 2-5.

### Example 2. Characterisation and Performance of PeLED Device 200 of the Current Invention

The as-fabricated PeLED ITO/ZnO/PEIE/FAPbI₃/Poly-TPD/MoO₃/Al device 200 from Example 1 was characterised as described in the methods section.

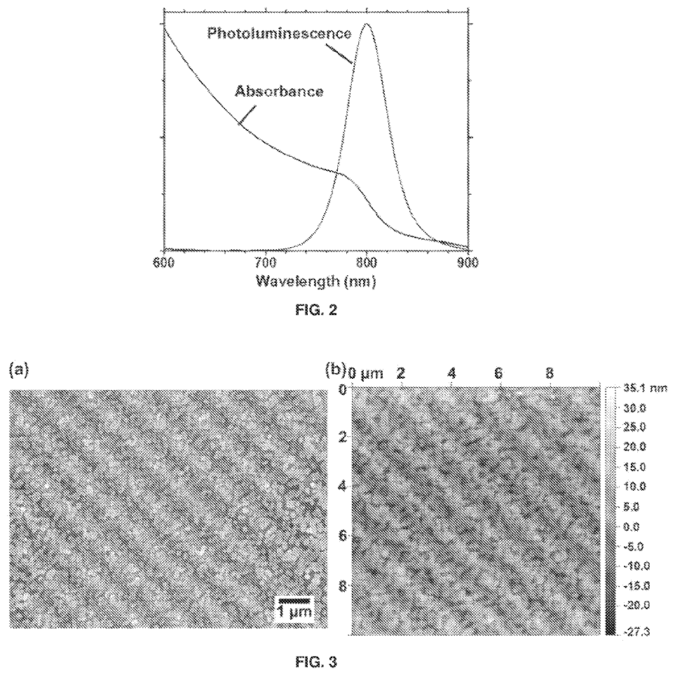

The absorbance and photoluminescence spectra of FAPbI₃ are shown in FIG. 2, and the scanning electron microscopy (SEM) and atomic force microscopy (AFM) image of the perovskite layer are shown in FIGS. 3a and b.

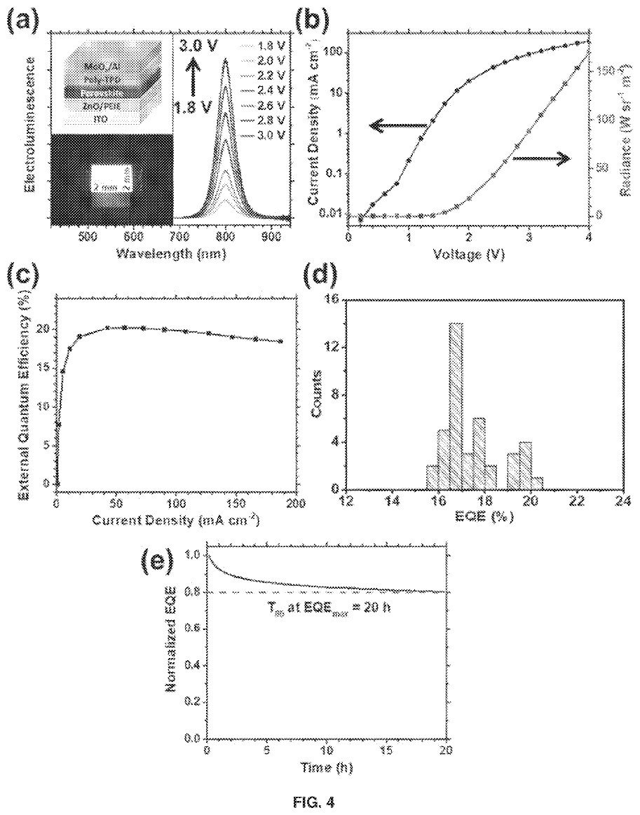

It was observed that the PeLED ITO/ZnO/PEIE/FAPbI₃/Poly-TPD/MoO₃/Al device 200 gave an emission at a NIR wavelength of 799 nm with a narrow full width at half maximum (FWHM) of 41 nm, which is consistent with photoluminescence measurements (FIG. 4a). The NIR emission suggests a bulk 3D perovskite structure rather than a quasi-2D structure that would have emissions at shorter wavelengths due to quantum confinement effects. A small-area 2×2 mm² PeLED device shows a high radiance of 170 W sr⁻¹ m⁻² at a driving voltage of 4.0 V and a current density of 187 mA cm⁻² (FIG. 4b). Remarkably, a high external quantum efficiency (EQE) of 20.2% was obtained at a high radiance of 57 W sr⁻¹ m⁻² and current density of 57 mA cm⁻² (FIG. 4c).

A total of 40 devices were fabricated using the same procedures, and they showed a high average EQE of 17.4%. It was observed that the device-to-device variation in performance was extremely narrow, with an EQE standard deviation of only 1.2%. The EQE distribution of the devices is shown in FIG. 4d.

Finally, the lifetime of the PeLED device 200 was also evaluated, as shown in FIG. 4e. The devices were continuously driven at a constant current density of 57 mA cm⁻², which corresponds to the operating condition with the highest EQE. The device also showed a respectable T₈₀ lifetime of 20 hours, which is the time taken for the radiance (or efficiency) to drop to 80% of its highest value. For the purpose of reference, the initial radiance of the lifetime test is over 100× the typical radiant output of a flat panel monitor display.

In order to determine the extent of efficiency enhancement through perovskite micro-structuring, the haze of the device stack was measured using a 990 nm diode laser. It was observed the PeLED device 200 showed a haze value of only 1.2%, which suggests light scattering and outcoupling effects are modest in the device of the current invention.

### Example 3. Mechanism of the Enhanced Performance of PeLED Device 200 of the Current Invention

Given that the use of triphenylamine-based poly-TPD as a hole-transport layer in device 200 of the current invention contributed to notable gains in the device efficiency, as well as a significant narrowing of device-to-device variation, the mechanism of the enhanced performance was investigated.

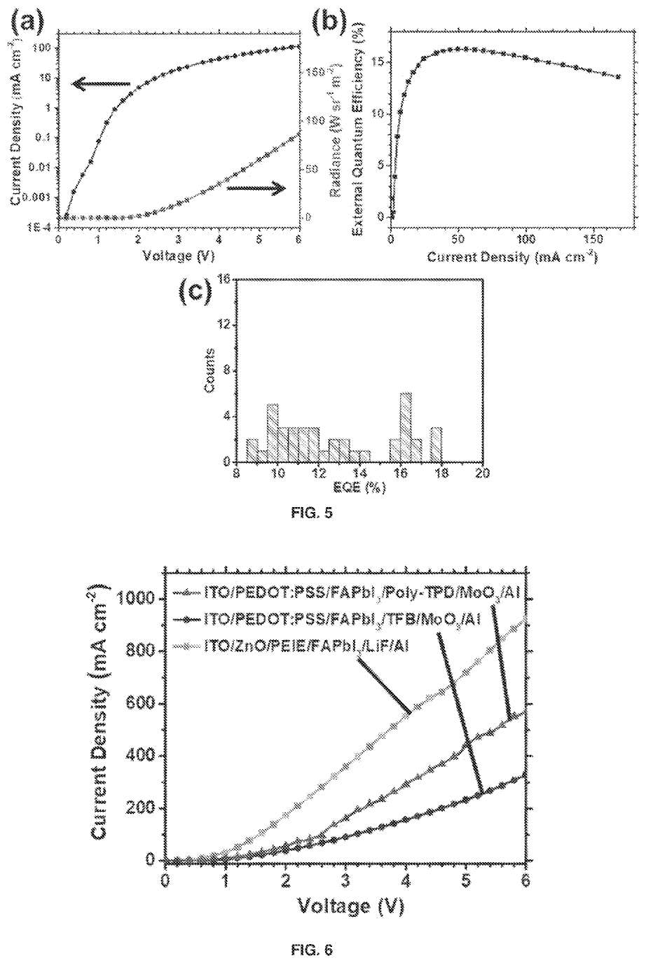

As comparison, control devices that employed the workhorse fluorene-based TFB (poly(9,9-dioctylfluorene-alt-N-(4-sec-butylphenyl)-diphenylamine)) were fabricated, and they showed average efficiencies of 12.9% with a significantly broader efficiency distribution (FIG. 5), which is lower than that of PeLED 200. Further, the standard deviation in the EQE of the 40 control devices was 2.9%, which is higher than that of PeLED 200.

In order to elucidate the mechanisms that led to the enhanced performance, single-carrier devices were fabricated (in Example 1) to investigate the effects of charge injection and transport behaviour across the device layers. FIG. 6 shows a comparison of the current density vs. voltage between an ITO/PEDOT:PSS/FAPbI₃/Poly-TPD/MoO₃/Al and an ITO/PEDOT:PSS/FAPbI₃/TFB/MoO₃/Al hole-only devices. An electron-only device with an ITO/ZnO/PEIE/FAPbI₃/LiF/Al structure was also tested for reference, and it represents the maximum electron current density that could be achieved across the perovskite layer. The hole-only device with poly-TPD show a distinct two-fold enhancement in hole current density (as compared to the hole-only device with TFB), suggesting an improvement to either hole injection, transport, or a combination of both. Importantly, the hole injection current from Poly-TPD/MoO₃/Al is better matched with the ohmic electron injection current from ZnO/PEIE, thereby confirming that a balanced charge injection into the perovskite layer is highly-beneficial in enhancing the performance of the device. It was observed that the current densities of the single-carrier devices were generally higher than that of the light-emitting diodes due to the absence of carrier-blocking layers in the design to enable single carrier transport.

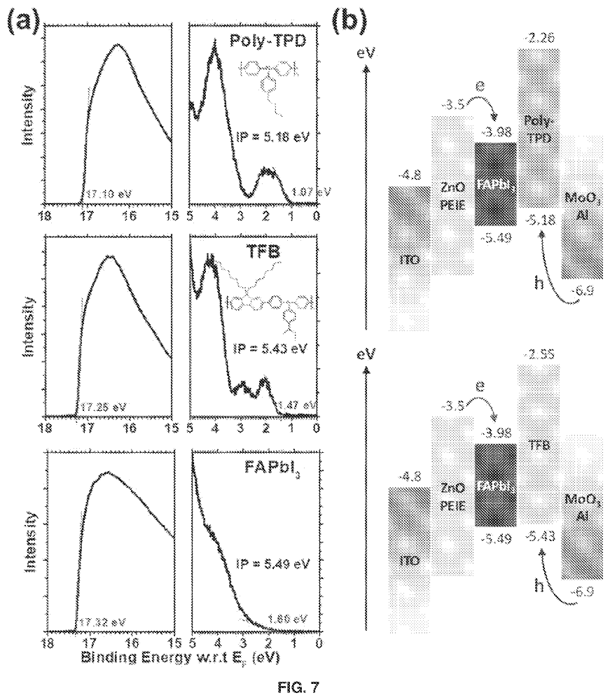

To further establish how the poly-TPD has led to an enhancement in hole-current density, the ionisation potentials of poly-TPD, TFB and FAPbI₃ were determined using ultraviolet photoelectron spectroscopy (UPS). As shown in FIG. 7a, poly-TPD possesses a shallower ionisation potential (IP) of 5.18 eV below vacuum level, while TFB has a deeper ionisation potential of 5.43 eV. This is consistent with theory that the electron-donating nitrogen in the triphenylamine makes poly-TPD an overall electron-richer semiconducting polymer. It is deduced that the shallower IP of poly-TPD leads to greater extent of hole-transfer doping from the MoO₃/Al electrode, in an effect known as Fermi-level pinning (Tan, Z.-K. et al. Adv. Fund. Mat. 2014, 24, 3051-3058; Tengstedt, C. et al. Appl. Phys. Lett. 2006, 88, 053502). This doping, in turn, leads to more efficient hole injection across the electrode/poly-TPD interface and into the perovskite emissive layer. An energy-level diagram that depicts the electronic bands of all layers in our device stack is shown in FIG. 7b.

Based on the above evidence, it was deduced that the problems of suboptimal device performance and large device-to-device variation in PeLEDs are significantly contributed by the less-efficient and imbalanced injection of holes into the hole-transport layer. Efficient operation of LEDs requires a delicate balance of electrons and holes in the emissive layer for radiative recombination. The excessive (or deficient) injection of any carrier leads to electrical current with no radiative contributions, which signifies a reduction in quantum efficiency. In the case of electron-current dominated PeLEDs, any minor differences in the limiting hole-injection current is therefore manifested as variations in the EQE. The two-fold enhancement in hole-injection efficiency through the deployment of poly-TPD ensures a balanced supply of holes for radiative recombination with electrons, and allows a consistently high efficiency to be achieved in the PeLED devices of the current invention.

### Example 4. Performance of a Large-Area PeLED Device 200 of the Current Invention

The highly-efficient and uniform performance of the PeLED device 200 of the current invention allow the fabrication of a large-area PeLED device without significant losses in efficiencies.

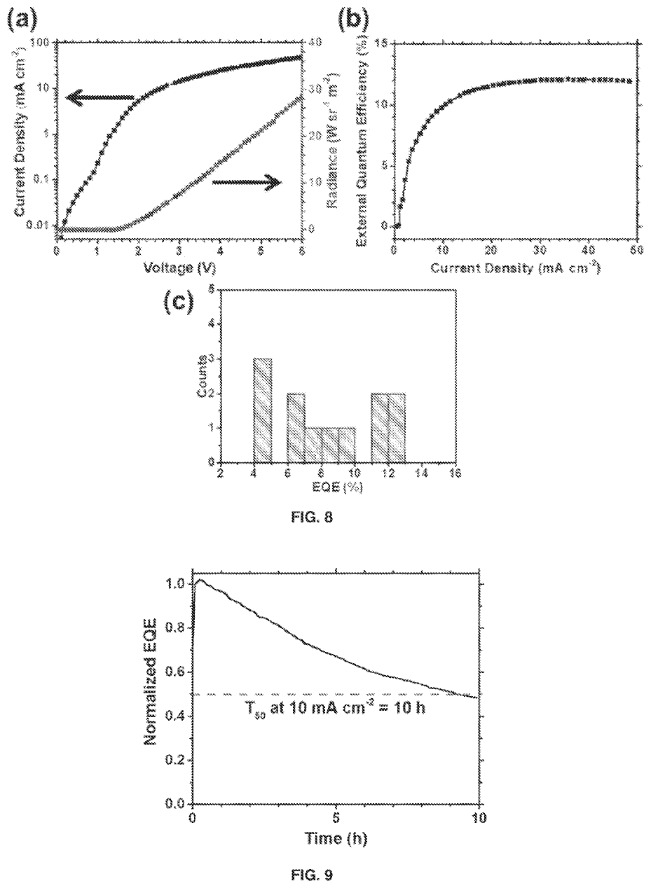

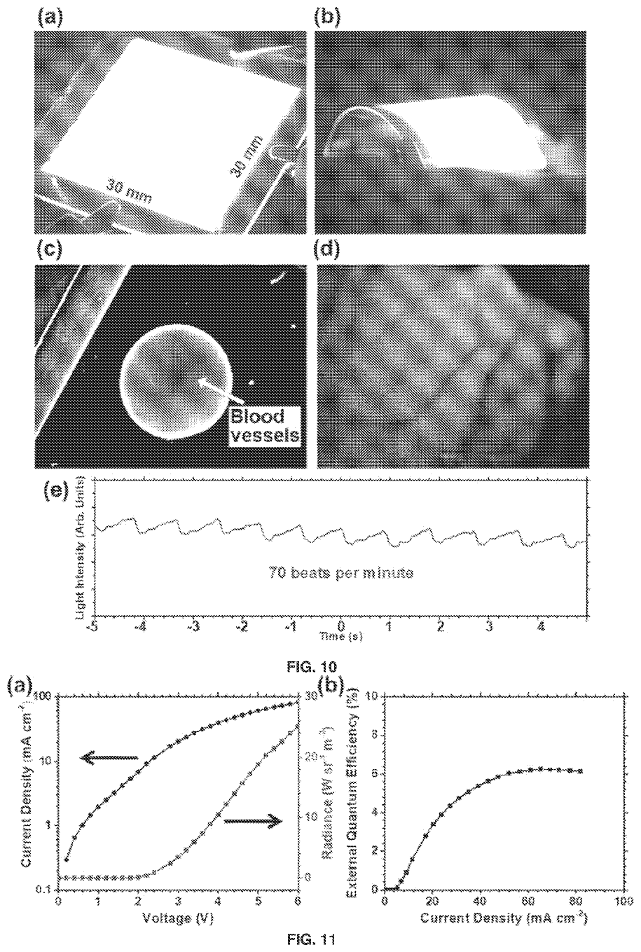

The PeLEDs device 200 with large active areas of 30×30 mm² (900 mm²) were fabricated, and their combined radiance and current density vs. voltage characteristics are shown in FIG. 8a. FIG. 8b shows the EQE vs. current density characteristics of the large-area device, and FIG. 10a shows the NIR photo of the device in operation. It was observed that the device efficiency remained remarkably high at 12.1% under high radiance operation (>20 W sr⁻¹ m⁻²), despite scaling to an area that is over two orders of magnitude larger. The photo also shows remarkably uniform light-emission across the entire 900 mm² device area, corroborating the uniform device-to-device performance observed in the corresponding small-area devices. The large-area device showed a good T₅₀ lifetime of 10 hours at a high current density of 10 mA cm⁻² (FIG. 9). A total of 12 large-area devices were fabricated and tested, and an average EQE of 8.2% with a standard deviation of 2.9% was obtained (FIG. 8c). For the purpose of comparison, a control device employing TFB with the same area operates with a lower EQE of 6.3% (FIGS. 11a and b), further validating the importance of an improved hole-transport layer.

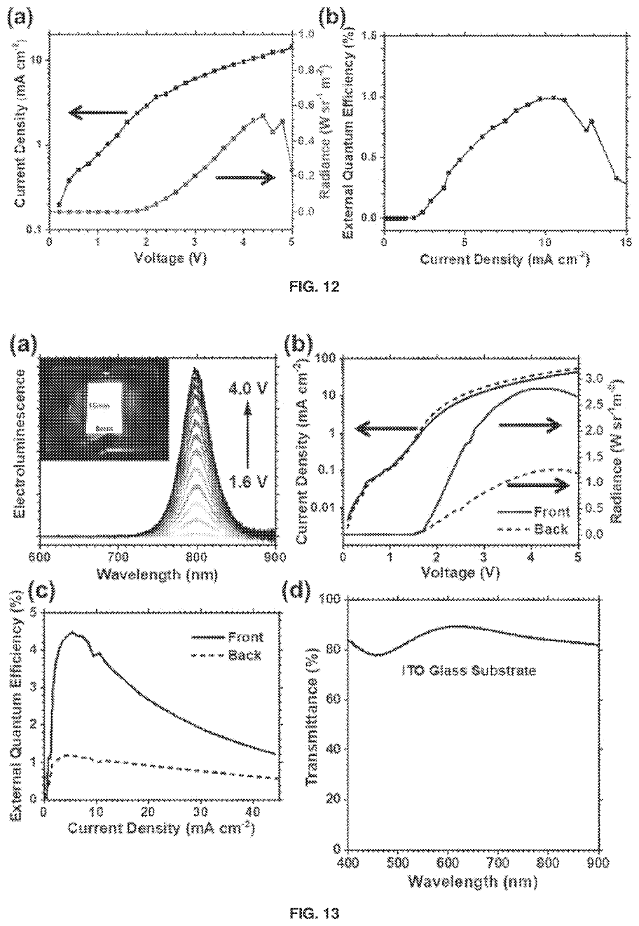

In order to demonstrate the versatility of the large-area processes, a 900 mm² PeLED 200 on a flexible polyethylene terephthalate (PET) substrate (FIG. 10b) was fabricated, thereby illustrating the possible applications of the current invention in wearable electronics that may require flexible form factors. The device characteristics of flexible large-area device 200 are shown in FIGS. 12a and b. The performance of the flexible device was modest (1.0% EQE) compared to the rigid devices, likely due to the difficulties in spin-coating uniform films on a flexible PET substrate and the poorer quality of the ITO layer.

### Example 5. Applications of PeLED Device 200 of the Current Invention in Wearable Medical Devices

The intense and uniform NIR emission in the large-area PeLED 200 allows potential application in new medical device technologies. As a proof of concept, a PeLED 200 with a circular window was constructed, and was used to illuminate an area of the human palm in close contact.

As shown in FIG. 10c, features of subcutaneous blood vessels are visible under the large-area PeLED 200, thereby validating the potential of the current invention in performing non-invasive deep-tissue illumination and imaging of the human body. FIG. 10d shows another photo of the PeLED 200 illuminating the back of a human fist at a distance. The illumination and distinction of subcutaneous deep-tissue structures is possible due to the fact that NIR wavelengths (850-950 nm) are less significantly absorbed and scattered by human tissues, and could therefore penetrate deeper into the body.

To further demonstrate the utility of the current invention in tracking subcutaneous blood flow, the PeLED 200 was coupled with a silicon photodiode, and was used to track the fluctuations in back-scattered NIR light due to changes in blood volume under the skin (FIG. 10e). This setup effectively functions as a localised blood volume and heart rate monitor (photoplethysmography).

### Example 6. Fabrication of Transparent PeLED Device 300 of the Current Invention

Besides device 200, a transparent PeLED device 300 of the current invention was fabricated with its various components as shown in FIG. 1c.

### Experimental

Pre-patterned indium tin oxide (ITO)-glass substrates (8 Ω/sq) were cleaned in a detergent solution, deionised water, acetone, and isopropanol for 10 min, sequentially, and then dried with a nitrogen gun. The substrates (with the glass and ITO denoted as 305 and 310, respectively, in FIG. 1c) were treated in a UV-ozone cleaner for 15 min before they were spin-coated with subsequent layers.

Aluminium-doped zinc oxide (AZO) nanoparticles (2.5 wt % in IPA, Avantama) were first deposited on an ITO-glass substrate by spin-coating at 5000 rpm for 1 min, followed by annealing at 140° C. for 10 min to form the electron transport layer 320. After cooling, a thin layer of polyethylenimine ethoxylated (PEIE, 0.4 wt % in 2-methoxyethanol), which functions as a low workfunction interlayer, was spin-coated at 5000 rpm for 1 min. The layers were annealed at 110° C. for 20 min.

The substrate was then transferred into a nitrogen-filled glove box for the deposition of subsequent layers. 80 μL of as-prepared formamidinium lead iodide (FAPbI₃) perovskite precursor solution (from general method 1) was spin-coated at 3000 rpm for 1 min, followed by annealing at 100° C. for 16 min to form the emission layer 330.

The poly-TPD (poly[N,N′-bis(4-butylphenyl)-N,N′-bisphenylbenzidine], American Dye Source) hole-transport layer 340 was spin-coated (over the emission layer 330) from a chlorobenzene solution with a concentration of 13 mg mL⁻¹.

Finally, MoO₃ (10 nm) and aluminium (10 nm) were sequentially thermal evaporated through a shadow mask at a pressure below 10⁻⁵ Torr, and was deposited on the hole transport layer 340. The substrates were then transferred into a sputtering system chamber (FHR) for deposition of ITO. Two layers of ITO (40 nm each) were deposited at room temperature by pulsed DC magnetron sputtering from a cylindrical rotatable ceramic target (In₂O₃:SnO₂, 97:3 wt %), using a 205 sccm gas flow (Ar:O₂, 98:2) at a DC power of 2 kW. The Ag interlayer (10 nm), between the ITO layers, was deposited by thermal evaporation at a pressure below 10⁻⁵ Torr. The MoO₃ layer functions as a high workfunction interlayer, with the Al/ITO/Ag/ITO layer being the electrode layer 350. The area of the device (defined by the overlap between the substrate ITO and the Al/ITO/Ag/ITO electrode) was determined to be 120 mm².

### Results and Discussion

A transparent PeLED device 300 was fabricated with an ITO/AZO/PEIE/FAPbI₃/poly-TPD/MoO₃/Al/ITO/Ag/ITO architecture (FIG. 1c). Notably, the top electrode 350 was designed with an interlayered Al (10 nm)/ITO (40 nm)/Ag (10 nm)/ITO (40 nm) structure to possess a combination of low sheet resistance and high optical transparency. The MoO₃/poly-TPD and AZO/PEIE layers were employed to facilitate ohmic and balanced injection of holes and electrons into the perovskite, respectively, for efficient electroluminescence. The as-fabricated device was characterised, with its performance evaluated as described in Example 7 and 8.

### Example 7. Characterisation and Performance of the Transparent PeLED Device 300 of the Current Invention

The as-fabricated transparent PeLED device 300 of Example 6 was characterised as described in the methods section.

FIG. 13a shows the electroluminescence spectra of the transparent PeLED 300 with characteristic NIR emission of FAPbI₃ at 799 nm. The device was fabricated with a large area of 120 mm² (15 mm×8 mm), and it showed show remarkably uniform emission across the entire active area (inset of FIG. 13a). FIG. 13b shows the combined current density vs. voltage, and radiance vs. voltage plots of the transparent PeLED 300. The device was turned on at a low voltage of −1.5 V, thus indicating efficient carrier injection from both electrodes (310 and 350).

Given that the transparent PeLED 300 contained transparent electrodes on both sides, the emission from the substrate side was defined as front emission, and that from the Al/ITO/Ag/ITO side was defined as the back emission. It was observed that the front emission was more intense and reached a maximum radiance of 2.8 W sr⁻¹ m⁻². On the other hand, the back emission showed a radiance of 1.2 W sr⁻¹ m⁻² at a driving voltage of 4.0 V, probably due to the higher transmittance of the front ITO glass substrate (FIG. 13d), as well as contributions of reflection from the thin metallic interlayers on the back electrode. As such, the external quantum efficiency (EQE) (FIG. 13c) was calculated to be 4.5% and 1.2% for the front and back emission, respectively, therefore giving a total EQE of 5.7% at a current density of 5.3 mA cm⁻² and a corresponding total radiance of 1.5 W sr⁻¹ m⁻².

While sputtered ITO appears to be a good material candidate for the back electrode for a transparent LED, it was observed that the thin polymer and perovskite active layers in a perovskite LED were particularly vulnerable to plasma damage from the ITO sputtering process, even when conducted at room temperature. This is unlike the thick layers that are employed in semi-transparent perovskite solar cells.

FIG. 14a shows the comparison of device characteristics between two PeLEDs having different back electrodes—one with an Al/ITO/Ag/ITO layer (i.e. device 300), and the other with a 500 nm ITO layer (sputtered at room temperature) as back electrode, respectively. The device 300 with Al/ITO/Ag/ITO shows a superior sheet resistance of 11 Ω/sq, which is lower that the sheet resistance of 30 Ω/sq obtained for PeLED with 500 nm ITO. Despite the higher sheet resistance, the PeLED that employed the 500 nm ITO shows a two orders-of-magnitude higher current density at <1.5 V (below device turn-on), indicating severe device shunts that resulted in high electrical current leakage. The radiance achieved by the 500 nm ITO PeLED is also notably lower at all driving voltages, as the leakage currents do not contribute to radiative recombination and are basically wasted as Joule heating.

Given this, a 10 nm Al interlayer was incorporated into the transparent PeLED 300 to reduce direct plasma damage to the underlying active layers. An ITO/Ag/ITO sandwiched electrode structure was also employed, first to reduce the amount of ITO that need to be sputtered in order to minimise damage, and also to provide remarkably low sheet resistance that is required for the device to operate efficiently.

FIG. 14b shows the comparison of optical transmittance between the Al/ITO/Ag/ITO and 500 nm ITO back electrodes, as well as that of their respective PeLEDs. The Al/ITO/Ag/ITO electrode and the transparent PeLED 300 both show reasonably flat transmittance profiles across the visible and NIR region, compared to the 500 nm ITO electrode that absorbs more-strongly in the blue spectral region. Notably, the Al/ITO/Ag/ITO PeLED possesses a high average transmittance of above 55% in the range of 450 to 650 nm, therefore allowing them to be technologically relevant for electronic trichromatic display applications. The spectral profile of a typical smart watch colour display and that of the NIR emission of PeLED 300 (denoted as “PeLED EL”) are shown in FIG. 14b for reference.

### Example 7. Application of the Transparent PeLED Device 300 of the Current Invention in a Wearable Device

The good NIR electroluminescence efficiency and optical transmittance of the transparent PeLED device 300 enables an exciting array of new covert illumination functions that was previously unachievable on small wearable gadgets.

As a proof-of-concept, the transparent PeLED 300 was overlaid over a smart watch, as shown in FIG. 15a. A high-contrast, neutral-density white display can be observed across the transparent PeLED 300, thus corroborating the above flat-spectral transmittance results. The PeLED 300 was operated at 3.2 V and the smart watch was imaged using a NIR camera, as shown in FIG. 15b. An intense NIR electroluminescence was observed, which masked out the features on the underlying visible display. This demonstration shows that the transparent PeLED 300 can be conceivably built onto a display to provide security and sensing functionalities, such as face recognition, eye-tracking, or motion and depth sensing that were only recently possible on larger tablet computers and phones.

1. A near infra-red light emitting diode (LED) device comprising a first electrode, a second electrode and a near infra-red emitter module sandwiched between the first and second electrodes, wherein the first and second electrodes are transparent.

2. The LED device according to claim 1, wherein the near infra-red emitter module comprises:
a hole transport layer;
an emission layer; and
an electron transport layer, where
the hole transport layer and electron transport layer sandwich the emission layer.

3. The LED device according to claim 2, wherein one or more of the following apply:
(a) the emission layer is formed from a material that has an optical energy gap of from 1.8 eV to 0.3 eV;
(b) the hole transport layer is formed from a polymeric material that has an ionisation potential of from 0 to −5.30 eV; and
(c) an energy difference between the first or second electrode and the hole transport layer, whichever the hole transport layer is adjacent to, is more than 1.50 eV.

4. The LED device according to claim 3, wherein the emission layer is formed from a semiconductor material.

5. The LED device according to claim 4, wherein the semiconductor material is a perovskite or quantum dots.

6. The LED device according to claim 5, wherein the perovskite has the formula:
ABX₃
wherein:
X is a halogen anion selected from one or more of Br, Cl, I;
A is a monovalent cation selected from one or more of Cs, an alkylammonium ion, and a formamidinium ion; and
B is a divalent cation selected from one or more of Pb and Sn.

7-8. (canceled)

9. The LED device according to claim 8, wherein the hole transport layer is formed from Poly-TPD.

10. The LED device according to claim 2, wherein the near infra-red emitter module further comprises one or both of:
(a) a low workfunction interlayer arranged next to the electron transport layer, said low workfunction interlayer is selected from one or more of the group consisting of polyethylenimine ethoxylated (PEIE), polyethylenimine (PEI), poly[(9,9-dioctyl-2,7-fluorene)-alt-(9,9-bis(3′-(N,N-dimethylamino)propyl)-2,7-fluorene)] (PFN), and LiF; and
(b) a high workfunction interlayer arranged next to the hole transport layer, said high workfunction interlayer is selected from one or more of the group consisting of MoO₃, WO₃, perfluorinated ionomer (PFI).

11. The LED device according to claim 10, wherein the near infra-red emitter module is one which has the following sequential layers:
an electron transport layer formed from aluminium zinc oxide;
a low workfunction interlayer formed from polyethylenimine ethoxylated (PEIE);
an emission layer formed from FAPbI₃;
a hole transport layer formed from poly-TPD; and
a high workfunction interlayer formed from MoO₃, where
the electron transport layer is in direct contact with the first electrode and the high workfunction interlayer is in direct contact with the second electrode, or vice versa.

12. The LED device according to claim 1, wherein one or both of the first and second electrode has an average transmittance of from 30 to 100% at a wavelength of from 400 to 700 nm and a sheet resistance of from 1 to 100 Ω/sq.

13. The LED device according to claim 1, wherein one or both of the first and second electrode is formed from an Al layer, a first layer of ITO, a Ag layer, and a second layer of ITO, where the first and second layers of ITO can independently be substituted for a layer of fluorine doped tin oxide (FTO), or a layer of silver nanowires.

14. The LED device according to claim 13, wherein one or more of the following apply:
the Al layer has a thickness of from 5 to 20 nm;
the first layer of ITO has a thickness of from 20 to 200 nm;
the Ag layer has a thickness of from 5 to 20 nm; and
the second layer of ITO has a thickness of from 20 to 200 nm, where the first and second layers of ITO can independently be substituted for a layer of fluorine doped tin oxide (FTO), or a layer of silver nanowires.

15. (canceled)

16. The LED device according to claim 1, wherein one of the first and second electrodes is formed from fluorine doped tin oxide (FTO), silver nanowires and indium tin oxide (ITO).

17. A near infra-red light emitting diode (LED) device comprising:
a first electrode and a second electrode;
a hole transport layer;
an emission layer; and
an electron transport layer, wherein:
the hole transport layer is formed from a polymeric material that has an ionisation potential of from 0 to −5.30 eV;
the hole transport layer and electron transport layer sandwich the emission layer; and
the first electrode is adjacent to the electron transport layer and the second electrode is adjacent to the hole transport layer, or vice versa.

18. The LED device according to claim 17, wherein an energy difference between the first or second electrode and the hole transport layer, whichever the hole transport layer is adjacent to, is more than 1.50 eV.

19. (canceled)

20. The LED device according to claim 17, wherein the semiconductor material is a perovskite or quantum dots.

21. The LED device according to claim 20, wherein the perovskite has the formula:
ABX₃
wherein:
X is a halogen anion selected from one or more of Br, Cl, I;
A is a monovalent cation selected from one or more of Cs, an alkylammonium ion, and a formamidinium ion; and
B is a divalent cation selected from one or more of Pb and Sn.

22-23. (canceled)

24. The LED device according to claim 17, wherein the near infra-red emitter module further comprises one or both of:
(a) a low workfunction interlayer arranged next to the electron transport layer, said low workfunction interlayer is selected from one or more of the group consisting polyethylenimine ethoxylated (PEIE), polyethylenimine (PEI), poly[(9,9-dioctyl-2,7-fluorene)-alt-(9,9-bis(3′-(N,N-dimethylamino)propyl)-2,7-fluorene)] (PFN), and LiF; and
(b) a high workfunction interlayer arranged next to the hole transport layer, said high workfunction interlayer is selected from one or more of the group consisting of MoO₃, WO₃, perfluorinated ionomer (PFI).

25. The LED device according to claim 24, which has the following sequential layers:
an electron transport layer formed from aluminium zinc oxide;
a low workfunction interlayer formed from polyethylenimine (PEIE);
an emission layer formed from FAPbI₃;
a hole transport layer formed from poly-TPD; and
a high workfunction interlayer formed from MoO₃, where
the electron transport layer is in direct contact with the first electrode and the high workfunction interlayer is in direct contact with the second electrode, or vice versa.

26-27. (canceled)

28. The LED device according to claim 27, wherein one or more of the following apply:
the Al layer has a thickness of from 5 to 20 nm;
the first layer of ITO has a thickness of from 20 to 200 nm;
the Ag layer has a thickness of from 5 to 20 nm; and
the second layer of ITO has a thickness of from 20 to 200 nm, where the first and second layers of ITO can independently be substituted for a layer of fluorine doped tin oxide (FTO), or a layer of silver nanowires.

29-30. (canceled)
